(19) United States
(12) Patent Application Publication
(10) Pub. No.: US 2003/0032285 A1
(43) Pub. Date: Feb. 13, 2003

(54) Vertical taper fabrication process of a narrow band wavelength division multiplexer

(76) Inventors: Alain M.J. Beguin, Vulaines Sur Seine (FR); Philippe Lehuede, Yerres (FR)

Correspondence Address: CORNING INCORPORATED, SP-TI-3-1, CORNING, NY, 14831

(21) Appl. No.: 09/929,456

(22) Filed: Aug. 13, 2001

(51) Int. Cl. H01L 21/302; H01L 21/461

(52) U.S. Cl. 438/689

(57) ABSTRACT

A method of fabricating a phased array narrow band wavelength division multiplexer including an arrayed waveguide, a slab waveguide and a transition region between the array waveguide and the slab waveguide comprising etching the transition region with a reactive ion etch to form vertically tapered waveguides between the arrayed waveguides.

### BACKGROUND OF THE INVENTION

1. Field of Invention

The present invention is directed generally to the fabrication of devices for optical communication, and more particularly to a method of fabricating a tapered narrow band waveguide division multiplexer.

2. Description of the Related Art

Wavelength division multiplexing is an efficient and cost effective way to exploit the bandwidth of optical fibers. Multiplexing is accomplished by devices, which can separate and recombine frequencies. One commonly used device is the phased-array wavelength division multiplexer that comprises both optical slabs (e.g. star couplers) and arrayed waveguides. A typical phased-array wavelength division multiplexer is illustrated in FIGS. 1a and 1b. The phased-array wavelength division multiplexer comprises multiple input waveguides 101 and output waveguides 109 connected to an input slab 103 and an output slab 107, respectively. Connecting the input slab 103 and the output slab 107 are arrayed guide waveguides 105.

Most of the loss in these devices occurs at the junctions, also known as the free propagation region (FPR), between the arrayed guide waveguides 105 and the slabs 103 and 107. FIG. 1b is an expanded view illustrating the free propagation region between the arrayed waveguides 105 and the output slab 107. At the free propagation region, loss occurs because of the deep modulation of the field in the array waveguides due to deep trenches between the array waveguides.

To reduce the depth of the modulation and increase the efficiency of the device, a shallowly filled transition region (TR) can be formed between the deeply etched arrayed waveguides and the free propagation region. FIG. 2 illustrates the location of this transition region relative to the arrayed waveguides and the free propagation region while FIG. 3 shows a perspective view of the transition region. Typically, the transition region is fabricated with a standard double etch technique.

FIGS. 4a-4e schematically illustrates a standard double etch technique through cross-section IV-IV in FIG. 3. An optical layer 403 is deposited on a substrate 401. Optionally, a buffer layer may be deposited between the substrate 401 and the optical layer 403. Then, a photo resist 405 is applied over the optical layer 403 and patterned to cover the slab region 417 and the arrayed waveguides (not shown). A gap is etched between individual arrayed waveguides in an array region 415 and a transition region 419 in a first etching step. Next, a second photo resist 407 is applied and patterned to cover the slab region 417, the transition region 419 and the arrayed waveguides. A second etch is performed to deeply etch the material between the arrayed waveguides in the arrayed region 415. Then, the photo resist is removed. The resulting structure has deeply etched gaps between the arrayed waveguides in the array region 415 and shallowly filled gaps between the arrayed waveguides in the transition region 419.

The addition of the transition region decreases the loss in the junction. This is because coupling between the free propagation region and the arrayed waveguides takes place in two steps, first in the transition region, then in the free propagation region.

Devices made by the standard double etch technique have lower losses than prior devices. However, there is a limit to the benefit of a transition region with a single shallowly filled gap thickness. A transition region with multiple steps, or ideally, a vertically tapered gap would yield an even more efficient device. However, use of the standard double etch technique requires masking, patterning and etching steps for each different material thickness, resulting in an unacceptable increase in the production costs of the device. Therefore, it would be advantageous to have a cost-effective method of manufacturing waveguide division multiplexers having a transition region with vertically tapered gaps between the arrayed waveguides.

### SUMMARY OF THE INVENTION

The present invention provides a method of fabricating a phased array narrow band wavelength division multiplexer including an arrayed waveguide, a slab waveguide and a transition region between the array waveguide and the slab waveguide comprising etching the transition region with a reactive ion etch, forming vertically tapered waveguides between the arrayed waveguides.

### BRIEF DESCRIPTION OF THE DRAWINGS

The foregoing and other features, aspects and advantages of the present invention will become apparent from the following description, appended claims and the exemplary embodiments shown in the drawings, which are briefly described below.

FIG. 1A is a plan view of a phased array multiplexer.

FIG. 2 is a schematic view of the transition region and the free propagation region of a phased array multiplexer with a shallowly etched transition region.

FIG. 3 is a perspective view of the prior art transition region.

FIGS. 4a to 4e schematically illustrate a standard double etch process.

FIG. 5 is a perspective view of a transition region made by the preferred method of the present invention.

FIGS. 6a and 6c schematically illustrate a preferred method of the invention.

FIG. 7 is a SEM picture of a device made according to the preferred embodiment of the invention.

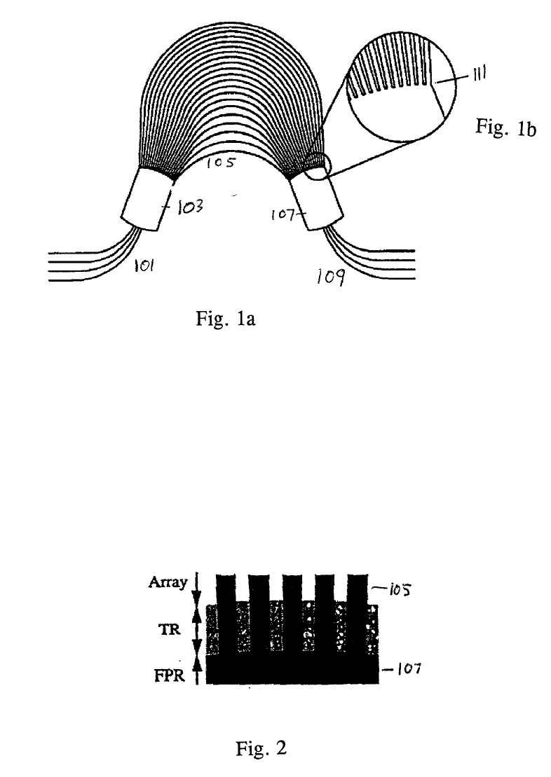

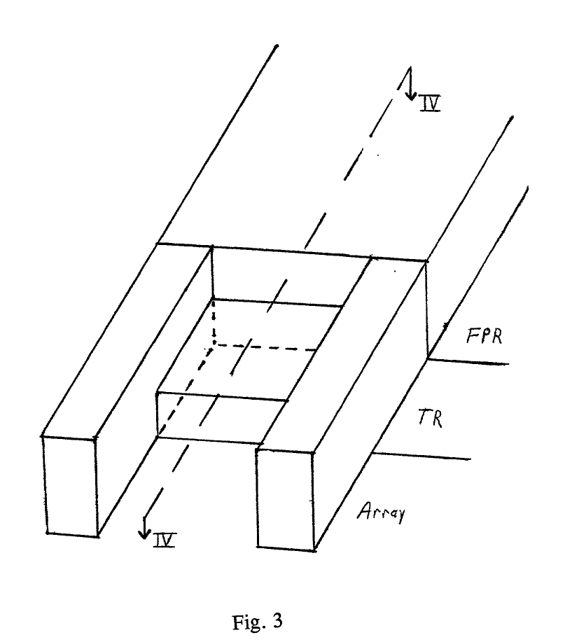

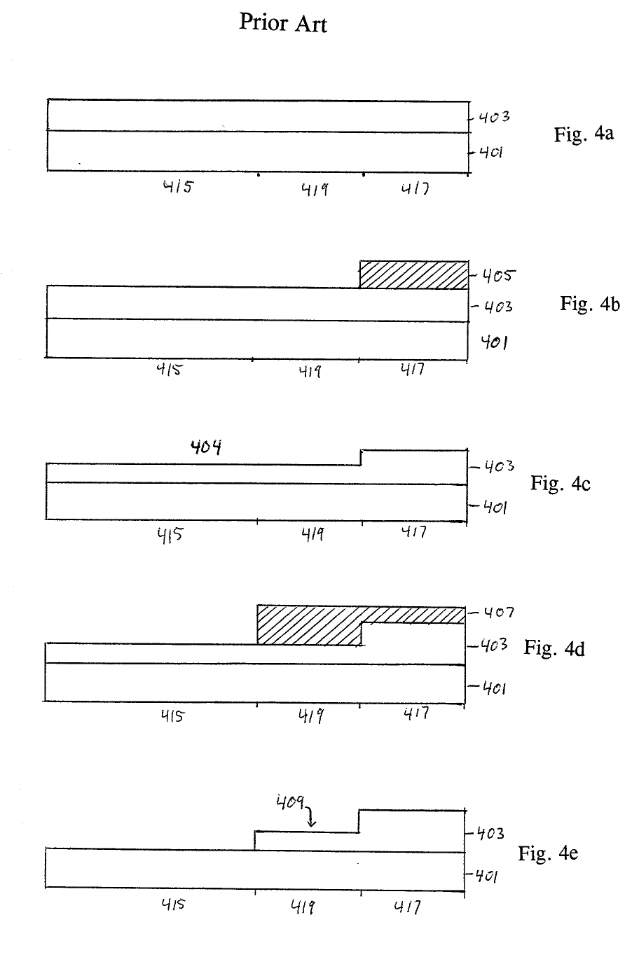

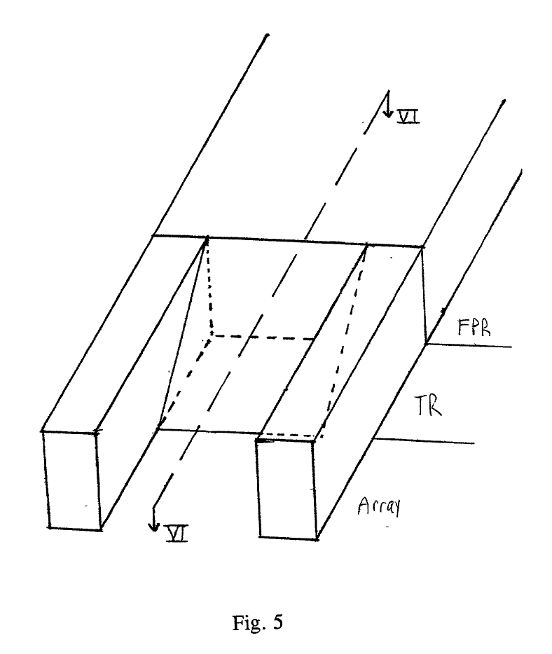

### DETAILED DESCRIPTION OF THE PREFERRED EMBODIMENTS

FIG. 5 is a perspective view of a transition region made by the preferred method of the present invention. As shown in the figure, it is preferable that the height of the material in the gap be equal to the slab height at the free propagation region and drop to zero at the end of the transition region. In the figure, the profile is linear. However, it is not necessary that the profile be linear. Indeed, the profile may be convex or concave as well. The shape of the profile is determined by the process parameters and will be discussed in more detail below.

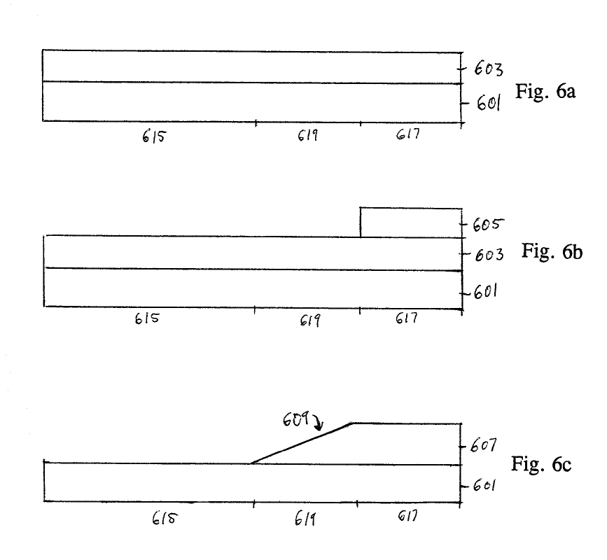

FIGS. 6a-6c illustrate the preferred method according to the present invention through cross-section VI-VI in FIG. 5. The method permits the formation of a tapered layer in the gap between the arrayed waveguides of a wavelength division multiplexer. In this embodiment of the invention, an optical layer 603 is deposited on a suitable substrate 601. Optionally, a buffer layer may be deposited between the substrate 601 and the optical layer 603. Then a photo resist 605 is applied and patterned to cover a slab region 617 and the waveguides (not shown). The transition region 619 and the gap between individual waveguides in the region 615 are etched in a single etching step by using a polymerizing etching gas mixture.

Unlike the standard etching procedure, the etching rate of a reactive ion etch with a polymerizing gas mixture is affected by the distance between adjacent arrayed waveguides. This is because there is lower bombardment and less renewal of etching gases in the confined area next to the slab relative to wide area in the array. Thus, in the transition region, where the waveguides come closer to each other, the etching depth becomes smaller and creates a “naturally” tapered region 609.

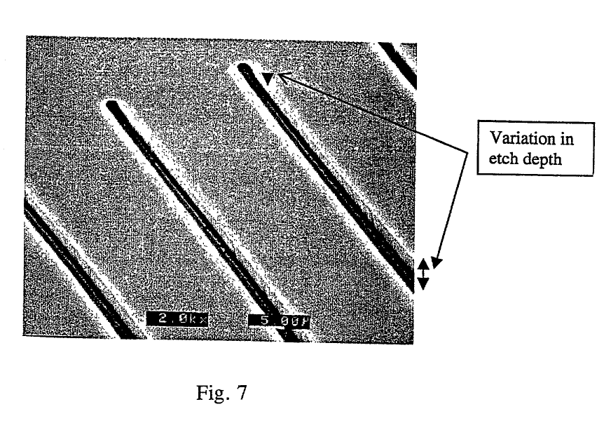

FIG. 7 is a scanning electron microscope picture of the transition region of a narrow band wavelength division multiplexer fabricated by the preferred method of the invention. The lighter areas in the lower portion of the micrograph correspond to the arrayed waveguides. The top portion of the micrograph corresponds to the slab region while the dark regions in the micrograph highlight the gaps between the arrayed waveguides. As can be seen in the figure, at the junction between the slab and the waveguides, the height of the material in the gap is the same as the height of the slab. However, the vertical depth of the gap increases with increasing distance from the junction. The resulting device has significantly improved loss characteristics over the prior art devices.

The shape of the tapered layer illustrated in FIG. 6c is linear. However, the shape of the taper can be varied by using different polymerizing gases or gas mixtures. A more isotropic mixture will tend to form a concave profile while a more anisotropic mixture will tend to produce a more convex profile. Preferred polymerizing gases include CF₄, C₂F₄, C₂F₆, C₃F₆, C₃F₈, C₄F₈, CHF₃, and CH₄. However, any polymerizing gas suitable for the etching of silica can be used.

Further, the preferred method comprises etching a doped silica core. However, undoped silica may also be vertically etched in an embodiment of the present invention. In addition, the preferred method of the invention results in a vertically tapered transition region in which the height of the vertically tapered waveguides is essentially the same as the height of the arrayed waveguides at a junction between the arrayed waveguide and the slab waveguide while the height of the vertically tapered waveguides gradually decrease with distance from the junction toward the arrayed waveguides.

Finally, the preferred method of the present invention is well suited for fabrication of narrow band wavelength division multiplexers. However, the method is suitable for fabricating any number of devices, which include closely spaced waveguides.

The foregoing description of the invention has been presented for purposes of illustration and description. It is not intended to be exhaustive or to limit the invention to the precise form disclosed, and modifications and variations are possible in light of the above teachings or may be acquired from practice of the invention. The drawings and description were chosen in order to explain the principles of the invention and its practical application. It is intended that the scope of the invention be defined by the claims appended hereto, and their equivalents.

We claim

1. A method of fabricating a phased array narrow band wavelength division multiplexer including an arrayed waveguide, a slab waveguide and a transition region between the array waveguide and the slab waveguide comprising:
etching the transition region with a reactive ion etch forming vertically tapered waveguides between the arrayed waveguides.

2. The method of claim 1, wherein the reactive ion etch includes at least one polymerizing gas.

3. The method of claim 2, wherein the polymerizing etch gas is a single component polymerizing gas chosen from the group consisting of CF₄, C₂F₄, C₂F₆, C₃F₆, C₃F₈ and C₄F₈ and CHF₃.

4. The method of claim 2, wherein the polymerizing etch gas is a gas mixture comprising multiple components chosen from the group consisting of CF₄, C₂F₄, C₂F₆, C₃F₆, C₃F₈, C₄F₈, CHF₃, SF₆, Cl₂, H₂ and CCl₃F.

5. The method of claims 3 or 4, wherein the transition region includes a doped silica core.

6. The method of claim 4, wherein the spacing between individual waveguides in the arrayed waveguide is smaller at the junction between the arrayed waveguide and the slab waveguide than away from the junction.

7. A phased array narrow band wavelength division multiplexer made by the method of claim 1.

8. The phased array narrow band wavelength division multiplexer of claim 6, wherein the height of least one of the vertically tapered waveguides is essentially the same as the height of the arrayed waveguide at a junction between the arrayed waveguide and the slab waveguide and wherein the height of the at least one vertically tapered waveguide gradually decreases with distance from the junction.

9. The tapered phased array narrow band wavelength division multiplexer of claim 6, wherein the transition region includes a doped silica core.

10. The tapered phased array narrow band wavelength division multiplexer of claim 6, wherein the spacing between individual waveguides in the arrayed waveguide is smaller at a junction between the arrayed waveguide and the slab waveguide than away from the junction.

11. A method of fabricating an optical device having closely spaced waveguides comprising:
etching a transition region with a reactive ion etch to form vertically tapered waveguides between the closely spaced waveguides.
